(19) United States
(12) Patent Application Publication
(10) Pub. No.: US 2024/0222168 A1
(43) Pub. Date: Jul. 4, 2024

(54) System and Method for Measuring Thermal Performance of Substrates used in Semiconductor Device Assembly

(71) Applicant: Western Digital Technologies, Inc., San Jose, CA (US)

(72) Inventors: Vishnu Chandar Janakiraman, PULAU PINANG (MY); Mutharasu Devarajan, PULAU PINANG (MY); Tomin Liu, PULAU PINANG (MY)

(73) Assignee: Western Digital Technologies, Inc., San Jose, CA (US)

(21) Appl. No.: 18/361,129

(22) Filed: Jul. 28, 2023

Related U.S. Application Data
(60) Provisional application No. 63/478,421, filed on Jan. 4, 2023.

(51) Int. Cl. H01L 21/67; H01L 21/66; H05B 1/02

(52) U.S. Cl. CPC H01L 21/67248; H01L 22/12; H05B 1/0233

(57) ABSTRACT

A heating system includes heating elements positioned within a housing and arranged in an array, and a plate positioned within the housing and above the plurality of heating elements. A thermochromic layer covers at least a portion of the top surface of the plate, and a camera is positioned above the plate. The camera is configured to record images of the thermochromic layer at the top surface of the plate, and a controller is in communication with the camera and configured to adjust the amount of power supplied to each heating element independent of one another. The thermochromic layer increases accuracy with which a temperature distribution of the plate can be determined at any point in time thereby enabling the controller to accurately adjust the amount of power supplied to the heating elements to achieve a generally homogeneous temperature distribution at the plate.

### CROSS-REFERENCE TO RELATED APPLICATIONS

This application claims the benefit of U.S. Provisional Patent Application No. 63/478,421 filed Jan. 4, 2023 entitled “System and Method for Measuring Thermal Performance of Substrates used in Semiconductor Device Assembly”, which is incorporated by reference herein in its entirety.

### BACKGROUND

The present disclosure generally relates to measurement systems and methods for measuring the thermal performance of a device or object and, more particularly, to systems and methods for measuring the thermal performance of substrates and semiconductor devices used in semiconductor device assembly.

Understanding the thermal performance of substrates and semiconductor devices and/or packages is important for determining operating performances and/or manufacturing or assembly constraints. For example, understanding the thermal performance of a substrate may be critical when trying to analyze potential solder joint stress during a thermal cycling test (TCT) (e.g., between 0° C. and 100° C.) and/or solder solidification temperature during reflow (e.g., between about 190° C. and 210° C.). In conventional heating systems and methods for measuring thermal performance, semiconductor devices are placed on a substrate and disposed in a heating system or oven and heated from a first temperature to a second temperature. However, conventional heating systems often do not achieve a uniform heat distribution such that different areas of the semiconductor devices are exposed to different amounts of heat. Put another way, semiconductor devices exposed to heat testing through conventional systems and methods are not exposed to a uniform temperature distribution. As such, any warpage in the semiconductor device may be misattributed to occur at higher or lower temperatures. Furthermore, accurately determining the heat distribution within conventional heating apparatuses is conventionally limited by the number of thermal measurement devices (e.g., thermocouples) that the apparatus supports. Therefore, there is a need to provide systems and/or methods of measuring the thermal performance of semiconductor devices that achieves a uniform distribution and/or accurately determining and accounting for an uneven heat distribution within a heating apparatus.

### SUMMARY

In one embodiment there is a heating system including a plurality of heating elements positioned within a housing, each of the heating elements being configured to generate an amount of heat based on an amount of power supplied to the respective heating element, a plate positioned within the housing, the plate having a bottom surface facing the plurality of heating elements and a top surface opposite the bottom surface, a thermochromic layer covering at least a portion of the top surface of the plate, a camera positioned above the plate, the camera configured to record one or more images of the thermochromic layer at the top surface of the plate, and a controller in communication with the camera and configured to adjust the amount of power supplied to each heating element independent of one another based on information derived from the one or more images.

In some embodiments, each heating element of the plurality of heating elements includes an infrared (IR) light emitting diode (LED). In some embodiments, the plurality of heating elements includes between 20 to 60 heating elements. In some embodiments, the plurality of heating elements includes at least 20 heating elements. In some embodiments, the plurality of heating elements includes 60 or more heating elements. In some embodiments, the one or more images recorded by the camera includes a plurality of color images of a top surface of the thermochromic layer recorded at different points in time and each color image of the top surface of the thermochromic layer at each point in time includes a visual indication of one or more colors visible at the top surface of the thermochromic layer.

In some embodiments, the controller is configured to automatically determine for each color image of the top surface of the thermochromic layer at each point in time, one or more temperature values for one or more areas of the thermochromic layer based on the visual indication of the one or more colors visible at the top surface of the thermochromic layer, and the controller is configured to automatically adjust the amount of power supplied to one or more heating elements based on the one or more temperature values. In some embodiments, the plurality of heating elements are arranged in an array and the plate is positioned above the plurality of heating elements, and the controller is configured to increase the amount of power supplied to one or more of the heating elements positioned below an area of the thermochromic layer having a temperature value that is less than a temperature value at one or more other areas of the thermochromic layer.

In some embodiments, the controller is configured to increase or decrease the amount of power supplied to the plurality of heating elements independent of one another while the plate is being heated by the plurality of heating elements such that the temperature of the plate is substantially homogeneous across the entire top surface of the plate. In some embodiments, a position of the plate relative to the one or more heating elements is adjustable.

In some embodiments, there is a method of measuring thermal performance of a semiconductor device component using the heating system, the method includes activating the plurality of heating elements by supplying each with an initial amount of power to cause the plate and thermochromic layer to be heated, at the camera, recording colors of the thermochromic layer while the thermochromic layer is being heated, and transmitting the recorded colors to the controller, at the controller, determining from the colors recorded by the camera that one or more areas of the thermochromic layer has a color that is different from a color of one or more other areas of the thermochromic layer and adjusting power supplied to one or more of the heating elements until a color of the thermochromic layer is substantially the same throughout, at the controller, generating power supply data including an indication of the amount of power supplied to each of the one or more heating elements that resulted in the color of the thermochromic layer being substantially the same throughout, and placing the semiconductor device component on the plate and activating the heating elements by supplying an amount of power to each of the heating elements based on the power supply data generated by the controller.

In some embodiments, prior to placing the semiconductor device component on the plate, the plate is cooled. In some embodiments, the initial amount of heat output is less than a maximum amount of heat output associated with each heating element. In some embodiments, the controller is configured to determine a temperature of one or more areas of the thermochromic coating based on the recorded color of the thermochromic coating.

In another embodiment, there is a method of measuring thermal performance of a semiconductor device component, the method including providing a heating system having one or more heating elements and a plate positioned above the one or more heating elements, the plate including a thermochromic layer applied to a top surface of the plate, activating the one or more heating elements to cause the plate and thermochromic layer to be heated and capturing a video recording of the thermochromic layer while the thermochromic layer is being heated, determining, based on the video recording of the thermochromic layer, a temperature profile of the plate, positioning a semiconductor device component on the plate, activating the one or more heating elements to cause the semiconductor device component to be heated, and in response to heating the semiconductor device component, determining one or more thermal performance characteristics of the semiconductor device component based on observed characteristics of the semiconductor device component and the determined temperature profile of the plate.

In some embodiments, the observed characteristics of the semiconductor device component include thermal induced warpage of the semiconductor device component. In some embodiments, the temperature profile of the plate includes an indication of one or more areas at the top surface of the plate having a temperature that is different from one or more other areas at the top surface of the plate. In some embodiments, the temperature profile is determined based on one or more colors of the thermochromic coating recorded in the video recording during heating of the thermochromic coating. In some embodiments, the heating system includes a controller configured to determine a temperature of one or more areas of the plate based on one or more colors of the thermochromic coating recorded in the video recording.

In another embodiment, there is a method of measuring thermal performance of a semiconductor device component, the method includes coating at least a portion of the semiconductor device component with an electrically insulating material and substantially covering the electrically insulating material with a thermochromic layer, at a reflow oven, heating the semiconductor device component and the thermochromic layer, while heating the semiconductor device component, capturing a video recording of the thermochromic layer, the video recording of the thermochromic layer including a visual indication of one or more visible colors at one or more areas of the thermochromic layer at different points in time, transmitting the video recording of the thermochromic coating to a processor, and at the processor, determining, based on the video recording of the thermochromic layer, a temperature profile of the semiconductor device component.

In some embodiments, one or more areas of the semiconductor device component experience warpage caused by the heating, and the method further includes associating, at the processor, the one or more areas of the semiconductor device component where warpage occurred with a respective temperature defined by the determined thermal profile to determine a warpage temperature, and adjusting an amount of heat output by the reflow oven to be below the determined warpage temperature.

### BRIEF DESCRIPTION OF THE DRAWINGS

The foregoing summary, as well as the following detailed description, will be better understood when read in conjunction with the appended drawings. For the purpose of illustrating the present disclosure, there are shown in the drawings embodiments, which are presently preferred, wherein like reference numerals indicate like elements throughout. It should be noted, however, that aspects of the present disclosure can be embodied in different forms and thus should not be construed as being limited to the illustrated embodiments set forth herein. The elements illustrated in the accompanying drawings are not necessarily drawn to scale, but rather, may have been exaggerated to highlight the important features of the subject matter therein. Furthermore, the drawings may have been simplified by omitting elements that are not necessarily needed for the understanding of the disclosed embodiments.

In the drawings:

FIG. 1A is a side cross-sectional view of a heating system in accordance with an exemplary embodiment of the present disclosure;

FIG. 1B is a top plan view of a portion of the heating system of FIG. 1A;

FIG. 2A is an example first image of a thermochromic layer of the heating system of FIG. 1A at a first point in time;

FIG. 2B is an example second image of the thermochromic layer of the heating system of FIG. 1A at a second point in time;

FIG. 3 is a flowchart illustrating a method of measuring thermal performance of a semiconductor device using the heating system of FIGS. 1A and 1n accordance with an exemplary embodiment of the present disclosure;

FIG. 4A is a side cross-sectional view of another heating system in accordance with an exemplary embodiment of the present disclosure;

FIG. 4B is a top plan view of a portion of the heating system of FIG. 4A;

FIG. 5 is a flowchart diagram illustrating a method of measuring thermal performance of a semiconductor device in accordance with another exemplary embodiment of the present disclosure;

FIG. 6 is a flowchart diagram illustrating a method of measuring thermal performance of a semiconductor device or one or more components thereof in accordance with another exemplary embodiment of the present disclosure; and

FIGS. 7A-7B are side cross-sectional views of a semiconductor device component prior to and after being coated with a thermochromic coating according to an embodiment.

### DETAILED DESCRIPTION

The present subject matter will now be described more fully hereinafter with reference to the accompanying Figures, in which representative embodiments are shown. The present subject matter can, however, be embodied in different forms and should not be construed as limited to the embodiments set forth herein. Rather, these embodiments are provided to describe and enable one of skill in the art.

In one embodiment, the systems and methods discussed herein include one or more computers or computing devices (e.g., the controllers referenced herein) having one or more processors and memory (e.g., one or more nonvolatile storage devices). In some embodiments, memory or computer readable storage medium(s) of memory store programs, modules and data structures, or a subset thereof, for a processor to control and run the various systems and methods disclosed herein. In one embodiment, a non-transitory computer readable storage medium having stored thereon computer-executable instructions which, when executed by a processor, performs one or more of any combination of the methods or steps disclosed herein. Numerous details are described herein in order to provide a thorough understanding of the example embodiments illustrated in the accompanying drawings. However, some embodiments may be practiced without any of the specific details, and the scope of the claims is only limited by those features and aspects specifically recited in the claims. Furthermore, well-known methods, components, and circuits have not be described in exhaustive detail so as not to unnecessarily obscure pertinent aspects of the embodiments described herein.

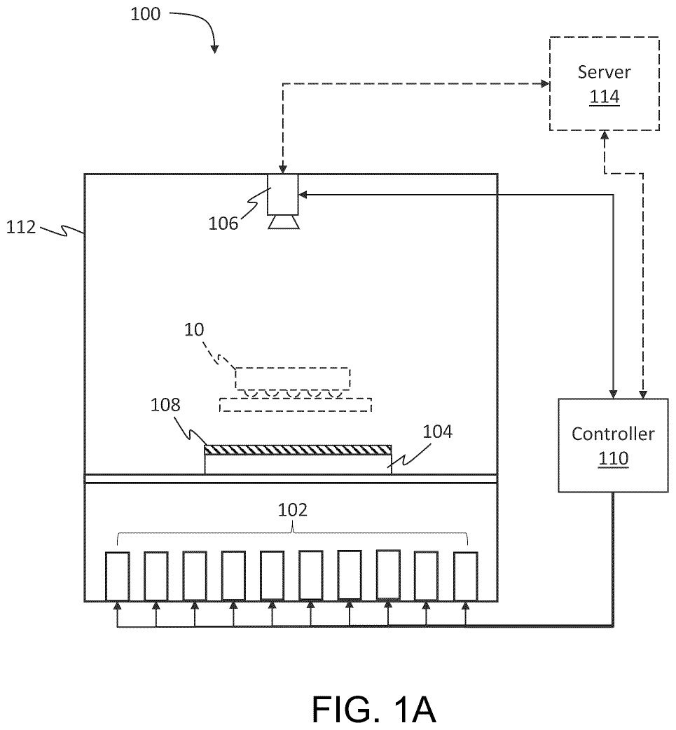

Referring to FIGS. 1A-1B, there is shown a heating system, generally designated 100, in accordance with an exemplary embodiment of the present disclosure. The heating system 100 may include one or more heating elements 102, a plate 104 positioned above the heating elements 102, and one or more image capture devices 106. In some embodiments, the one or more heating elements 102 and the plate 104 are positioned within a housing 112. The heating system 100 may include a thermochromic layer 108 disposed on the plate 104, and a controller 110 in communication with the one or more heating elements 102 and the one or more image capture devices 106. In some embodiments, the thermochromic layer 108 covers some or all of the top surface of the plate 104. In some embodiments, the thermochromic layer 108 covers at least a central portion of the plate 104. In some embodiments, the thermochromic layer 108 substantially covers the top surface of the plate 104. In some embodiments, the thermochromic layer 108 is configured to provide a visual indication of the relative temperatures of the top surface of plate 104.

The thermochromic layer 108, in some embodiments, is configured to exhibit different visible colors when heated to different temperatures. Different portions of thermochromic layer 108 may have different colors when the different portions are at different temperatures. For example, an edge or corner portion of the thermochromic layer 108 may show a different color than a central portion of the thermochromic layer 108 if such portions are heated to different temperatures. In some embodiments, the thermochromic layer 108 will exhibit a substantially homogeneous color only when all areas of thermochromic layer 108 are at substantially the same temperature. The thermochromic layer 108 may be comprised of Vanadium Oxide (V₂O₅) or any other suitable thermochromic material. In some embodiments, the thermochromic layer 108 may undergo a chemical doping process to selectively alter properties such as, but not limited to, the visible colors corresponding to different temperatures and/or the thermal stability of the thermochromic layer 108. For example, the color of the thermochromic layer at a specific temperature may be altered by doping different metal ions with V₂O₅. In some embodiments, the thermochromic layer 108 may provide a visual indication as to one or more temperatures of the plate 104 during a heating cycle.

A heating cycle may refer to the plate 104 being heated from a first temperature to a second temperature over a first period of time, and from the second temperature back to the first temperature over a second period of time. For example, during a heating cycle the plate 104 may be heated from about 30° C. to about 260° C. over a first period of time and then cooled from about 260° C. to about 30° C. over a second period of time. During the heating cycle, the thermochromic layer 108 may change colors in response to temperature changes of the plate 104.

In some embodiments, the controller 110 is configured to determine a temperature distribution of the plate 104 based on one or more images of the thermochromic layer 108 recorded by the one or more image capture devices 106 and automatically adjust an amount of power supplied to one or more of the heating elements 102. For example, there may be a power source (not shown) in communication with the one or more heating elements 102 and the controller 110 may be configured to increase or decrease the amount of heat output by the one or more heating elements 102 by adjusting the amount of power supplied to each by the power source. The amount of power supplied to each of the heating elements 102 may be determined, at least partially, based on the color information of the thermochromic layer 108 (e.g., colors visible at the top surface) that are included in the images recorded by the one or more image capture devices 106. The controller 110 may, for example, be configured to determine the color information from the images recorded by the one or more image capture devices 106.

In some embodiments, the one or more heating elements 102 are arranged in an array (e.g., as illustrated in FIG. 1). For example, in FIG. 1B, there are ninety individual heating elements 102 illustrated and arranged in a 9×10 array. In some embodiments, the heating elements 102 may be arranged in evenly spaced rows and/or evenly spaced columns in the array. Heating elements 102 may be arranged in other array shapes and sizes according to other embodiments. Each of the heating elements 102 may be positioned below the plate 104 and oriented generally upward such that heat output by the heating elements 102 is directed upward. In this manner, the heat output by one or more of the heating elements 102 may be directed primarily toward the plate 104. In some embodiments, the heating elements 102 are oriented generally perpendicular to the bottom surface of the plate 104. In some embodiments, there are between about ten to about one hundred heating elements 102 included in the heating system 100. In other embodiments, the heating system 100 includes about twenty to about sixty heating elements 102. The one or more heating elements 102 may be, in some embodiments, infrared (IR) heating elements configured to heat the plate 104 via infrared light. For example, each heating element 102 of the plurality of heating elements 102 may be an IR light emitting diodes (LED).

The plate 104 may be configured to receive a device for which thermal testing and/or measurements are desired. For example, a semiconductor device and/or package, generally designated 10, may be placed onto the plate 104 and the one or more heating elements 102 may be activated to cause the plate 104 and the semiconductor device 10 to be heated. In some embodiments, the plate 104 is a quartz substrate. However, the plate 104 may be comprised of any suitable material for performing thermal testing or gathering thermal measurements. In some embodiments, the position of the plate 104 relative to the housing 112 is adjustable. Put another way, the plate 104 may be positioned at a plurality of positions within the housing 112. As such, the position of the plate 104 relative to the one or more heating elements 102 may not be fixed. For example, in FIG. 1B, the position of the plate 104 (shown in broken lines) is illustrated in a first position relative to the housing 112 and the one or more heating elements 102.

In some embodiments, the heating elements 102 may be distributed over an area that is the same or larger than the area (e.g., the top or bottom surface area) of plate 104. In other embodiments, the heating elements 102 may be distributed over an area that is less than the area of plate 104. In some embodiments, plate 104 may be generally centered over the array of heating elements 102. In some embodiments, plate 104 may be moveable with respect to the heating elements 102. In FIG. 1B, the plate 104 is shown positioned above the heating elements 102 located above the heating element 102 located in the fourth row and fourth column (as counted from the top left corner), the heating element 102 located in the seventh row and seventh column, and all heating elements 102 in between. Put another way, in FIG. 1B the plate 104 is located generally centrally above the array of heating elements 102. In some embodiments, and as illustrated in FIG. 1B, the array of heating elements 102 may be positioned within a surface area that is greater than the surface area of the bottom surface, or top surface, of the plate 104. As such, a portion of the heating elements 102 may be positioned directly below the plate 104 whereas a remaining portion of the heating elements 102 may not be directly below the plate 104. For example, in FIG. 1B, the circular shapes (representing the heating elements 102) that intersect and/or are located within the broken line rectangle (representing the plate 104) may be directly below the plate 104 and the remaining heating elements 102 may not be directly below the plate 104. In some embodiments, one or more heating elements 102 adjacent the heating elements 102 below the plate 104 may be referred to as being proximate the plate 104. For example, the heating elements 102 within the area outlined by the dash-dot-dash broken line illustrated in FIG. 1B, but exterior to the dashed broken line (representing the plate 104) may be referred to as being proximate the plate 104. It should be understood though that the location of the plate 104 and the area illustrated by the dash-dot-dash broken line are for illustrative purposes only.

In some embodiments, the controller 110 is configured to determine the position of the plate 104 and/or thermochromic layer 108 relative to the one or more heating elements 102. For example, the controller 110 may determine the location of the plate 104 and/or thermochromic layer 108 relative the one or more heating elements 102 based on an image of the plate 104 and/or thermochromic layer 108 generated by the image capture device 106. Furthermore, the position of the one or more heating elements 102 within the housing 112 may be fixed and the controller 110 may have stored thereon position data for each of the heating elements 102 indicating their respective positions within the housing 112. In this manner, the controller 110 may be configured to determine which of the heating elements 102 are below and/or proximate the plate 104 based on the position of the plate 104 within the housing 112. In some embodiments, the controller 110 is configured associate one or more of the heating elements 102 with one or more different areas of the plate 104 based on the determined position of the plate 104 and the position data for each of the heating elements 102. For example, in FIG. 1B, the controller 110 may associate the heating element in the seventh row and fourth column with being below the lower left corner area of the plate 104.

As discussed above, the thermochromic layer 108 when heated, may change colors. As such, at one or more points in time, there may be one or more colors visible at the top surface of the thermochromic layer 108. For example, at a first point in time there may be two or more different colors visible at two or more different areas of the top surface of the thermochromic layer 108 and at a second point in time there may be a single color visible. The visible colors may generally provide a visual indication as to the temperature of different areas of the plate 104 at specific points in time. As such, the image capture device 106 may be configured to generate one or more color images of the top surface of the thermochromic layer 108 at one or more points in time. Each color image generated by the image capture device 106 may include a visual indication of one or more colors visible at the top surface of the thermochromic layer 108 at the corresponding point in time. For example, each color image may include a plurality of pixels each having an associated color value, such as, but not limited to an RGB value, HSV value, HSL value, CMYK value, CMY value, or any other color value associated with a color model known to those skilled in the art. For sake of brevity, it will be assumed that color images as discussed herein include a plurality of pixels each having an associated color value (e.g., RGB value).

In some embodiments, the image capture device 106 is a camera 106 configured to record the thermochromic layer 108 during a heating cycle. The recording by camera 106 may include a video recording and/or one or more still images of the thermochromic layer 108. The video recordings and/or still images are preferably recorded in a digital format. The terms image capture device 106 and camera 106 may be used interchangeably herein. A recording generated by the camera 106 may include one or more color images of the thermochromic layer 108 at one or more points in time during a heating cycle. For example, if a heating cycle occurs over a thirty-minute period of time, the camera 106 may capture color images of the thermochromic layer 108 at different points in time over the thirty-minute period (e.g., at one second, two seconds, three seconds, and so on). In some embodiments, the controller 110 is configured to cause the camera 106 to capture color images at a predetermined interval. For example, the controller 110 may cause the camera 106 to capture a color image of the thermochromic layer 108 at a predetermined interval of between about every half second to every thirty seconds. In some embodiments, the predetermined interval is about one second.

In some embodiments, the one or more color images included in the recording generated by the camera 106 may be transmitted to the controller 110 such that the controller 110 may determine the temperature of the plate 104 and/or thermochromic layer 108 at corresponding points in time. The controller 110 may be configured to generate a temperature heat map of the plate 104 and/or thermochromic layer 108 based on the received color images. For example, the controller 110 may be configured to convert the RGB values included in the color image into temperature values, and thereby generate a temperature heat map of the plate 104 and/or thermochromic layer 108. The generated temperature heat map may include temperature values at different locations on the plate 104 and/or thermochromic layer 108.

In some embodiments, the camera 106 transmits the recorded color images of the thermochromic layer 108 in real-time to the controller 110. For example, in response to generating a first color image of the thermochromic layer 108 at a first point in time, the camera 106 may transmit the first color image at the first point in time to the controller 110. Furthermore, in response to generating a second color image at a second point in time following the first, the camera 106 may transmit the second color image to the controller 110 at the second point in time. This process may be repeated over a period of time (e.g., during a heating cycle of the plate 104). As such, at each point in time in which the controller 110 receives a color image from the camera 106, the controller 110 may automatically determine one or more temperature values for one or more areas of the thermochromic layer 108 and/or plate 104 based on the received color image. For example, each color image may include a visual indication of one or more colors visible at the top surface of the thermochromic layer 108. The controller 110 may automatically determine, based on the visual indication of one or more colors, a temperature value corresponding to the visual indication.

In some embodiments, there is a server 114 in communication with the controller 110 and/or camera 106 that is configured to automatically determine the temperature heat map, or temperature profile, based on received color images. For example, the controller 110 may be configured to cause the camera 106 to transmit color images at a predetermined interval to the server 114. In some embodiments, the server 114 is configured to cause the camera 106 to capture and transmit the color images. In response to receiving a color image, at a point in time, the server 114 may be configured to automatically generate a temperature heat map including temperature values at different locations on the plate 104 and/or thermochromic layer 108. The server 114, in some embodiments, may include one or more processors configured to generate temperature data based on the received color images. In some embodiments, for example, the one or more processors may be configured to associate an actual or relative temperature value with a particular color value (e.g., RGB value, CMYK value, etc.) from the color image (e.g., for an individual pixel or a group of pixels). In some embodiments, the server 114 is configured to determine an associated temperature value for each pixel in a color image or only a subset of pixels in the color image. In some embodiments, the one or more processors may be configured to calculate an average color value for a group of pixels in a color image (e.g., a group of adjacent pixels) and associate the average color value with an actual or relative temperature value.

In some embodiments, the server 114 is configured to generate a temperature heat map or temperature profile based on the temperature values associated with the color values for one or more or each of the color images. In some embodiments, the server 114 is configured to generate the temperature heat map via a machine learning (ML) program, or software application (e.g., image processing software), installed or run on the server 114. The program or software may instruct the one or more processors to perform the functions described herein. In some embodiments, by determining, at the server 114, the temperature heat map via a ML program, the amount of data analysis may be reduced when compared to conventional methods. For example, the ML program may be trained to identify trends and/or patterns in the color images and may be configured to process multivariate data included in, for example, the color images. The server 114 may be configured to, in response to generating the temperature heat map, automatically transmit the generated temperature heat map to the controller 110. In this manner, the controller 110 may be configured to receive temperature heat maps at different points in time during a heating cycle and adjust heat output in real time (as described in more detail below) without human intervention.

In some embodiments, the server 114 may be configured to more accurately and/or more quickly determine the temperature heat map, or temperature, profile than conventional devices and/or methods implementing manual data analysis and/or inputs. As such, by providing the server 114 in communication with the controller 110 as described above, the heating system 100 may be configured to accurately achieve temperature homogenization in a rapid manner (e.g., within a matter of seconds). Furthermore, as the accuracy of the determined temperature heat map or profile is increased, the accuracy with which the heating system 100 may determine thermal induced warpages of semiconductor devices 10 may also be increased.

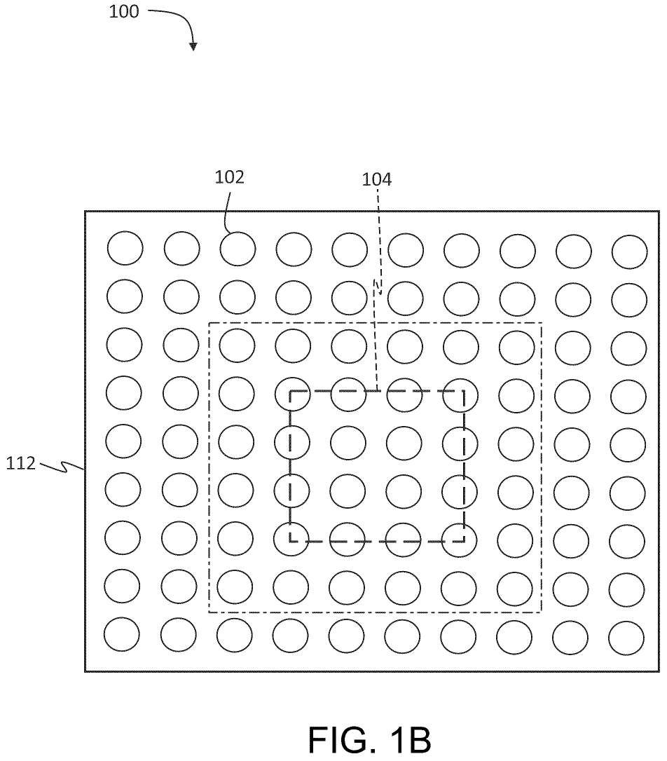

For example, and referring to FIGS. 2A-2B, example images representing color images of the thermochromic layer 108 generated by the camera 106 at two different points in time are shown. The density of the dotted pattern shown in FIGS. 2A-2B are intended to represent a visual indication of a different color. For example, in FIG. 2A, there image shown includes a plurality of different densities of the dotted pattern at different areas of the thermochromic layer 108 and in FIG. 2B, the image shown includes generally a uniform dotted pattern throughout the entire surface of the thermochromic layer 108. As such, in FIG. 2A, there may be a visual indication of a plurality of colors at different areas of the thermochromic layer 108 whereas in FIG. 2B, there may be a visual indication of a single color across the entire top surface of the thermochromic layer 108. It should be understood though that what is shown in FIGS. 2A-2B are intended to illustrate visual indications of one or more colors at different points in time and are for purposes of describing aspects of the present disclosure. Furthermore, it should be understood that what is shown in FIGS. 2A-2B are examples and that color images generated by the camera 106 may include any combination of visual indications of color(s) at any number of areas of the thermochromic layer 108.

In FIG. 2A, at time T=1, the image capture device 106 may transmit a color image of the top surface of the plate 108 to the controller 110. The controller 110 may determine, generally at time T=1, one or more temperatures of the plate 104 based on one or more colors of the thermochromic layer 108. In this manner, the controller 110 may receive, in real time, color images of the thermochromic layer 108 such that the controller 110 may determine, based on visual indications of colors at the top surface of the thermochromic layer 108, one or more temperatures of the thermochromic layer. For example, in an instance where the color image shown in FIG. 2A is transmitted to the controller 110, the controller 110 may automatically convert the visual indication of different colors appearing in the image received at time T=1 to one or more temperature values for one or more areas of the thermochromic layer 108. As such, at time T=1, the controller 110 may convert the RGB values included in the color image into a temperature heat map of the thermochromic layer 108. The controller 110 may be configured to determine temperature variations at different points across the entire surface of the thermochromic layer 108 based on the generated temperature heat map. In this example, the controller 110 may determine that temperature values for areas proximate the lower left region of the thermochromic layer 108 are less than temperature values for areas proximate the upper right region.

The controller 110 may be configured to automatically determine, for each color image of the top surface of the thermochromic layer 108 at each point in time, one or more temperature values for one or more areas of the thermochromic layer 108 based on the visual indication of the one or more colors visible at the top surface of the thermochromic layer 108. In some embodiments, the controller 110 is configured to determine, for a plurality of areas at the top surface of the thermochromic layer 108, an average temperature value. For example, in FIGS. 2A-2B, the dashed broken lines illustrate a grid wherein each square represents a different area at the top surface of the thermochromic layer 108 that the controller 110 may determine an average temperature for. It should be understood though that the dashed broken line grid is for illustrative purposes only and may not be visible in a color image transmitted from the camera 106 to the controller 110. In this manner, the controller 110 may be configured to determine whether the temperature of the plate 104 is generally homogeneous. Furthermore, it should be understood that the number of areas depicted in FIGS. 2A-2B, represented by the individual squares, are an example and in instances where the controller 110 is configured to determine an average temperature for a plurality of areas there may be more or fewer areas included in the plurality than what is shown in FIGS. 2A-2B. In FIG. 2A, for each area included in the plurality of areas, the controller 110 may determine based on the visual indication of colors present in that area, an average temperature for that area. In this manner, the controller 110 may determine an average temperature for any number of areas of the thermochromic layer based on the visual indication.

In some embodiments, the controller 110 is configured to automatically adjust the amount of power supplied to one or more of the heating elements 102 based on the one or more temperature values determined by the controller 110. In some embodiments, the controller 110 may adjust the amount of power supplied to the one or more heating elements 102 at the point in time in which the temperature values are determined. For example, in response to determining, at time T=1, that one or more areas of the thermochromic layer 108 have a temperature that is different from one or more other areas, the controller 110 may adjust the amount of power supplied to one or more of the heating elements 102 at time T=1. Adjusting the amount of power supplied to a heating element 102 may cause the heating element to increase or decrease the amount of heat output therefrom. As such, in response to determining that there is a difference in temperature of the thermochromic layer 108, and therefore the plate 104, the controller 110 may automatically adjust the power supplied to one or more of the heating elements 102, independent of one another to achieve a generally homogeneous temperature distribution. In some embodiments, if controller 110 determines that no area of thermochromic layer has reached a predetermined temperature (e.g., a selected target temperature), controller 110 may increase the power supplied to one or more heating elements 102 until the predetermined temperature has been reached.

In some embodiments, the controller 110 may adjust the amount of power supplied to the heating elements 102, independent of one another, based on the location of the heating elements relative to the different areas of the thermochromic layer 108. For example, and as discussed above with reference to FIG. 1B, the controller 110 may have stored thereon, position data indicating the position of each of the heating elements relative to different areas of the plate 104 and/or thermochromic layer 108. As such, the controller 110 may associate the temperature values at different areas of the plate 104 and/or thermochromic layer 108 with heating elements 102 below those areas. The controller 110 may automatically adjust the amount of power supplied to the heating elements 102 below the different areas of the thermochromic layer 108 and/or plate 104 based on the corresponding temperature values. For example, in FIG. 2A, the controller 110 determines that the lower left areas of the thermochromic layer 108, and therefore the plate 104, have lower temperature values than the upper right areas. As such, the controller 110 may determine which heating element(s) 102 are below the lower left area and increase the amount of power supplied thereto while not adjusting the amount of power supplied to the heating element(s) below the upper right area. Alternatively, or in combination with the previous example, the controller 110 may decrease the amount of power supplied to the heating element(s) below the upper right area.

In some embodiments, the controller 110 may repeat the process of receiving a color image of the thermochromic layer 108, determining one or more temperature values for one or more different areas and adjusting the amount of power supplied to one or more of the heating elements 102 such that the temperature distribution of the plate 104 and/or thermochromic layer is generally homogeneous. For example, at time T=1, the controller 110 adjusts the amount of power supplied to one or more of the heating elements 102 to cause the plate 104 and/or thermochromic layer 108 to have a generally homogenous temperature distribution at time T=2, as illustrated in FIG. 2B. A generally homogenous temperature distribution may refer to the difference in temperature between the highest and lowest determined temperature values for the plate 104 being within a predetermined temperature variation tolerance (e.g., +/−1° C.). In this manner, the controller 110 may be configured to determine that the temperature across the top surface the plate 104 and/or thermochromic layer is non-homogeneous and automatically adjust the amount of heat output by one or more of the heating elements 102 independent of one another to achieve a homogeneous temperature distribution.

The optical bandgap of the thermochromic layer 108 may change in color linearly in response to changes in temperature. Because the variation in color change may be linear, the predetermined temperature variation tolerance may be less than +/−1° C. In some embodiments, the predetermined temperature variation tolerance may be dependent on the camera 106 used to capture images of the thermochromic layer 108 and/or software used to analyze the captured images. For example, the resolution of the camera 106 may affect the ability of the camera 106 and/or software to detect changes in color of the thermochromic layer 108, which may directly correlate to the accuracy of determined temperature values. For example, cameras 106 having a higher resolution may result in more accurate determined temperature values when compared to cameras 106 having a lower resolution.

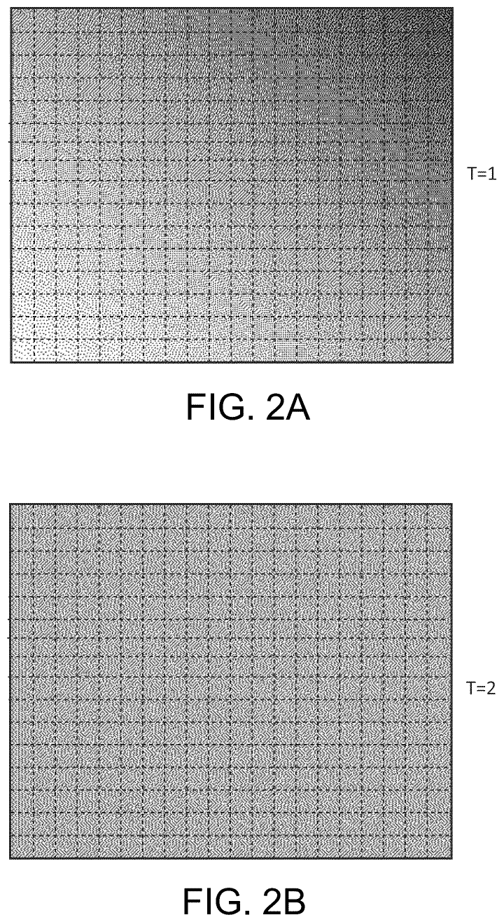

Referring to FIG. 3, there is shown a flowchart diagram illustrating a method, generally designated 200, of measuring the thermal performance of a semiconductor device component using the heating system 100 and in accordance with an exemplary embodiment of the present disclosure. In some embodiments, the heating system 100 may be configured to automatically determine one or more heat output values for one or more points in time to achieve a homogeneous heat distribution of the heating plate 104 throughout a heating cycle. A heating cycle, as discussed above, includes heating the plate 104 from an initial temperature to a desired maximum temperature and then cooling the plate from the desired maximum temperature back to the initial temperature, or another desired temperature. Put another way, a heating cycle includes a period of increasing the temperature of the plate 104 and a period of decreasing the temperature of the plate 104.

The method 200 may include the step 202 of beginning an initial heating cycle of the plate 104 while no semiconductor device (e.g., semiconductor device 10) is placed on the plate 104. Prior to beginning the initial heating cycle the plate 104 may be placed at a location within the housing 112 and above one or more heating elements 102. As discussed above, the controller 110 may be configured to determine the location of the plate 104 relative to the heating elements 102 and it will be assumed, for sake of brevity, that the controller 110 has stored thereon position data relating to the position of the plate 104 relative to the one or more heating elements 102. At the beginning of the initial heating cycle each of the heating elements 102 may begin outputting an initial amount of heat. For example, the controller 110 may provide an initial amount of power to each of the heating elements 102 to cause the heating elements to output an initial amount of heat thereby heating the plate 104 and thermochromic layer 108. In this manner each of the heating elements 102, at an initial point in time when the initial heating cycle begins, is provided a generally equal amount of power such that the initial amount of heat output by each is generally equal. In some embodiments, the initial amount of power supplied to each of the heating elements 102, and therefore the initial amount of heat output therefrom, is less than a maximum of the heating elements 102. For example, the initial amount of power supplied to each heating element, and therefore the initial amount of heat output therefrom, may be about 50% of the maximum for the heating elements 102 to enable the controller 110 to increases or decreases to the amount of output heat at a later point in time.

In some embodiments, the controller 110 may be configured to generate power supply data including an indication of the amount of power supplied to each of the one or more heating elements 102 during the initial heating cycle. In some embodiments, the controller 110 may be configured to generate the power supply data in response to a change in the amount of power supplied to one or more of the heating elements 102. For example, at the point in time in which step 202 occurs, the amount of power supplied to the heating elements may change from being generally zero to an initial amount of power. As such, the controller 110 at the initial point in time in which step 202 occurs, may generate power supply data that includes an indication of the amount of power supplied to each of the one or more heating elements and an indication of that initial point in time. The generated power supply data may be stored (e.g., in a non-transitory computer readable storage medium) by the controller 110 for later reference.

The method 200 may include the step 204 of recording the temperature of the plate 104. For example, the step 204 may include, at the camera 106, recording colors of the thermochromic layer 108 while the thermochromic layer 108 is being heated. As discussed above, the recording generated by the camera 106 may include one or more color images or a video recording including a visual indication of colors visible at the top surface of the thermochromic layer 108. As such, the camera 106 may generate to the controller a first color image at a first point in time, a second color image at a second point in time and so on.

The method 200 may include the step 206 of determining whether different colors are visible on the top surface of the thermochromic layer 108. The controller 110 may be configured determine whether one or more areas of the thermochromic layer 108 has a color that is different from a color of one or more other areas (e.g., as illustrated in FIG. 2A). For example, in response to receiving a color image from the camera 106 at a point in time, the controller 110 may determine whether the visual indication of colors visible at the top surface of the thermochromic layer 108 indicates there are different colors visible. As discussed above the different colors visible at the top surface of the thermochromic layer 108 indicate different temperatures at different areas of the plate 104 at a point in time. Such differences in temperature at different areas of the plate 104 may occur, for example, because of uneven heating by the one or more heating elements 102.

The method 200 may include the step 208 of adjusting an amount of power supplied to one or more of the heating elements 102 in response to determining that one or more areas of the thermochromic layer has a color that is different from a color of one or more other areas. For example, and as discussed above, the controller 110 may, at a point in time, selectively adjust the amount of power supplied to one or more of the heating elements 102 independent of one another. In some embodiments, the steps 204-208 are repeated until the controller 110 determines that a color of the thermochromic layer is substantially the same throughout. Put another way, the steps 204-208 may be repeated until the controller 110 determines that the temperature distribution across substantially the entire top surface of the thermochromic layer 108 is generally homogeneous.

The method may include the step 210 of generating power supply data in response to a color of the thermochromic layer being substantially the same throughout. For example, at a point in time in which the controller 110 determines that the color of the thermochromic layer is substantially the same throughout, the controller 110 may generate and store power supply data. The power supply data may include an indication of the amount of power supplied to each of the one or more heating elements that resulted in the color of the thermochromic layer being substantially the same throughout. In some embodiments, the power supply data also includes an indication of the time at which an amount of power was adjusted. For example, the power supply data may include an indication, for each heating element 102 included in the plurality of heating elements, a power supply amount and a specific amount of time as measured from the start of the initial heating cycle at step 202. In this manner, the controller 110 may be configured to automatically adjust the heat output of the heating elements 102 and generate a data record of power supply amounts and corresponding times for achieving a generally homogeneous temperature distribution of the plate 104 and/or thermochromic layer 108 during a heating cycle.

In some embodiments, the method 200 may include the step 212 of determining whether the heating cycle has completed. In some embodiments, determining whether the heating cycle is complete is based on a predetermined heating cycle time. For example, a heating cycle, including the heating and cooling of the plate 104 and thermochromic layer 108, may be desired to be performed over a predetermined period of time (e.g., ten minutes, twenty minutes, thirty minutes, an hour, more than an hour) and the controller 110 may be configured to determine an amount of time elapsed from the start 202 of the initial heating cycle. Alternatively, the determination of whether the initial heating cycle has completed is based on whether the plate 104 has been heated, throughout, from an initial temperature to a desired maximum temperature, and then cooled from the desired maximum temperature back to the initial temperature or a predetermined final temperature. In response to determining that the heating cycle is not complete the steps 204-212 may be repeated any number of times.

In this manner, the controller 110 may continue to automatically generate power supply data over the course of an entire heating cycle. The power supply data generated by the controller 110 during the initial heating cycle may include an indication, at different points in times during the heating cycle, of the amount of power supplied to each of the heating elements 102 for achieving a generally homogeneous temperature distribution of the plate 104 and/or thermochromic layer 108. Put another way, the controller 110 may automatically adjust the amount of power supplied to each of the heating elements 102 one or more times during a heating cycle and record the power supply amounts at different points in time in order to generate power supply data corresponding to generally homogeneous temperature distributions of the plate 104 at different points in time.

In some embodiments, the steps 202-212 may be repeated any number of times after the initial heating cycle has completed in order to further improve the temperature homogeneity of the plate 104 during a heating cycle. For example, steps 202-212 may be repeated generally the same as what is described above except that the amount of power supplied to the heating elements 102 at different points in time may initially be based on the previously generated power supply data. The steps 204-212 may be repeated in generally the same manner as described above except that the generation of power supply data may include the creation of new power supply data and/or updates to the existing power supply data. For example, the existing power supply data may that at a first time the amount of power supplied to a specific heating element should be X and at a second time the power supplied to that heating element should be Y. During a following heating cycle in which the steps 202-212 are repeated, it may be determined by the controller 110 that there are different colors visible at the thermochromic layer 108 between the first and second time. As such, the controller 110 may generate new power supply data including an indication of an amount of power to supply at a third time occurring between the first and second times. Alternatively, the controller 110 may update the existing power supply data to edit at least one of the power supply values of X and Y and/or edit at least one of the time values for the first and second time.

In some embodiments, performing the steps 202-212 once is sufficient to generate power supply data that is usable to perform a heating cycle during which the temperature of the thermochromic layer 108, and therefore the plate 104, is generally homogeneous throughout. In some embodiments, the method 200 may include the step 214 of placing a semiconductor device on the plate 104 and/or thermochromic layer 108, and performing a heating cycle according to the power supply data generated in steps 202-212. In some embodiments, the step 214 may include placing a semiconductor device 10 (e.g., a semiconductor device component) on the plate 104 and activating the heating elements 102 by supplying an amount of power to each of the heating elements 102 based on the power supply data generated by the controller 110. For example, the controller 110 may supply an amount of power to each of the heating components 102 based on the indication of a power supply amount and a point in time included in the power supply data generated during the initial heating cycle. In this manner, the heating system 100 of the present disclosure may be used to measure the thermal performance of a semiconductor device or component thereof while ensuring that the temperature of the plate 104 is generally homogeneous at generally each point in time during the heating cycle. In some embodiments, prior to performing step 214, the plate 104 may be cooled back to an initial temperature.

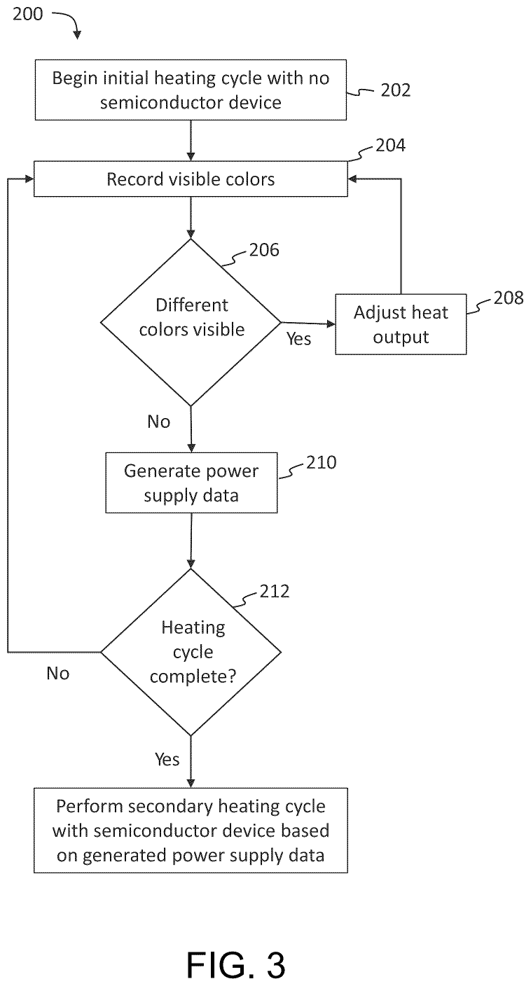

Referring to FIGS. 4A-4B there is shown a heating system, generally designated 300, for use in a method in accordance with another exemplary embodiment of the present disclosure. The heating system 300 may include one or more heating elements 302, a plate 304, a camera 306, a thermochromic layer 308, a controller 310, and a housing 312. The heating system 300 may be generally the same as the heating system 100 except that the heating system 300 may include one or more heating elements 302 different from the heating elements 102. The heating elements 302 may be different from the heating elements 102 in that they are arranged in a single row or column as opposed to being arranged in an array. In some embodiments, the heating system 300 may include a single heating element 302. In some embodiments, the amount of heat output by each of the heating elements 302 may be fixed, or put another way, the amount of heat output by each of the heating elements 302 may not be adjustable by the controller 310. As such, in heating system 300, the controller 310 may not be configured to adjust an amount of power supplied to the heating elements 302 in response to one or more different temperatures of the plate 304.

The plate 304 and thermochromic layer 308 may be generally the same as the plate 104 and thermochromic layer 108. For example, the plate 304 may be positioned above the one or more heating elements 302 and the thermochromic layer 308 may be applied to the top surface of the plate 304. The thermochromic layer 308 may substantially cover the top surface of the plate 304. The camera 306, and housing 312 may be generally the same as the image capture device 106, also referred to as camera 106, and housing 112 of the heating system 100. In some embodiments, the heating system 300 includes a server 314 in communication with the camera 306 and/or controller 310 and configured to generate a heat map at different points in time during a heating cycle in generally the same manner as described above with reference to server 114.

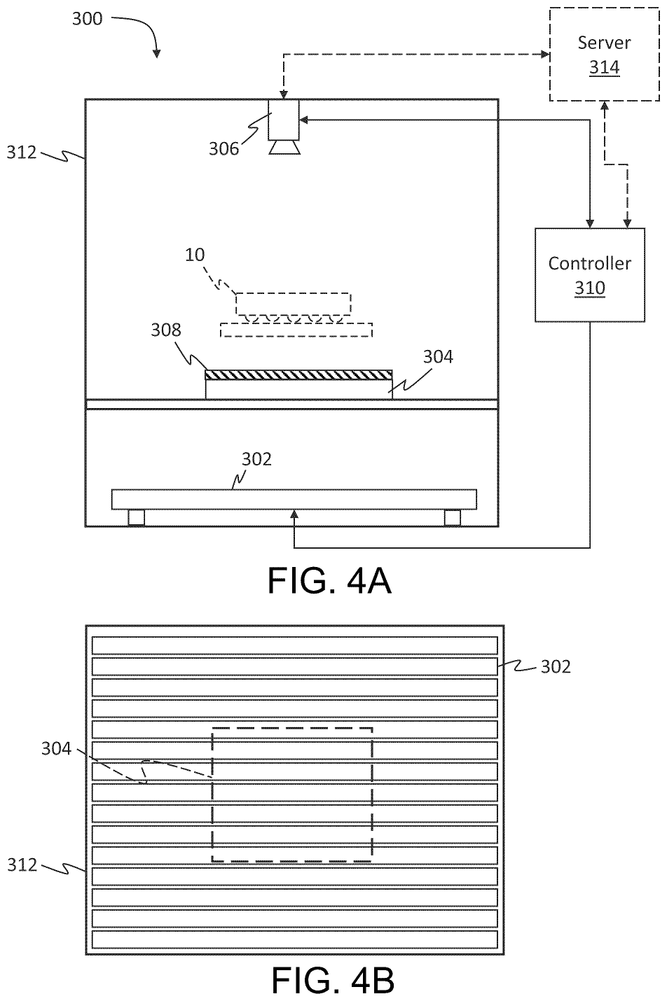

Referring to FIG. 5, there is shown a flowchart illustrating a method, generally designated 400, of measuring the thermal performance of a semiconductor device component in accordance with another embodiment of the present disclosure. The method 400 is described herein as being performed using the heating system 300 as discussed above with reference to FIGS. 4A-4B, however it should be understood that any other heating system described herein may be used to perform the method 400.

The method 400 may include the step 402 of beginning an initial heating cycle with no semiconductor device or component thereof placed on the plate 304. Initiating the heating cycle at step 402 may include supplying a fixed amount of power to the heating elements 302. The method 400 may include the step 404 of recording visible colors of the thermochromic layer 308. For example, the camera 306 may generate a video recording of the thermochromic layer 308 during the heating cycle (e.g., as the thermochromic coating is heated and/or cooled). The video recording generated by the camera 306 may be generally the same as the recording generated by camera 106 as discussed above. For example, the video recording may include one or more color images of the thermochromic layer 308 at one or more points in time during the heating cycle. Each of the one or more images included in the recording may include a visual indication as to one or more colors at one or more different areas of the thermochromic layer 308 at different points in time.

The method 400 may include the step 406 of determining, based on the video recording of the thermochromic layer 308, a temperature profile of the plate 304 (e.g., a temperature heat map). For example, the camera 306 may transmit the video recording to the controller 310 which may determine one or more temperature values for one or more different areas of the plate 304 at one or more points in time during the initial heating cycle. The controller 310 may determine the one or more temperature values for the one or more different areas at the one or more points in time in generally the same manner as discussed above with reference to controller 110 and FIGS. 1A-3. For example, the controller 310 may be configured to convert the color values (e.g., RGB values) included in the color image into temperature values and generate a temperature heat map accordingly. In some embodiments, the temperature profile determined by the controller 310 may be stored as temperature profile data by the controller 310. The temperature profile data may include an indication of the one or more determined temperature values, an indication of the one or more corresponding areas, and an indication of the one or more corresponding points in time. In this manner, the controller 310 may generate temperature profile data that generally includes an indication of the temperatures at different locations of the plate 304 at different points in time between the beginning and end of the initial heating cycle. In some embodiments, the generated temperature profile data may be transmitted from the controller 310 to an external computing device (e.g., computing device external to the heating system 300) for later reference.

The method 400 may include the step 408 of performing a secondary heating cycle with a semiconductor device (e.g., semiconductor device 10) or a component thereof placed on the plate 304. For example, the step 408 may include positioning a semiconductor device component on the plate 304 and activating the one or more heating elements 302 to cause the semiconductor device component to be heated. In some embodiments, the heating elements 302 are supplied with substantially the same amount of power as done in the initial heating cycle. In some embodiments, the position of the semiconductor device component relative to the plate 304 may be recorded. For example, the location of the semiconductor device component on the plate 304 may be determined by the controller 310 based on one or more images captured by the camera 306. As such, the controller 310, in some embodiments, may generate component location data including an indication of the areas of the plate 304 upon which the semiconductor device component covers. Put another way, the component location data may include an indication as to the location of the semiconductor device component relative to one or more points on the plate 304. In some embodiments, the camera 306 and/or one or more other image capture devices may record the semiconductor device component while undergoing the secondary heating cycle. As such, the recording may be analyzed (e.g., by the controller 310 and/or a human) to determine at what time during the secondary heating cycle the observed characteristic occurred. For example, in an instance where the observed characteristic is a thermal warpage, the video recording may be analyzed to determine at what time the thermal warpage begins to occur.

The method 400 may include the step 410 of determining, or measuring, the thermal performance of the semiconductor device component based on the determined temperature profile. In some embodiments, prior to the step 410, the plate 304 may be cooled to an initial temperature following the initial heating cycle. In some embodiments, the step 410 includes in response to heating the semiconductor device component, determining the thermal performance characteristics of the semiconductor device component based on observed characteristics of the semiconductor device component and the determined temperature profile of the plate 304. For example, one or more areas of the semiconductor device component, during heating, may experience a thermal warpage. However, it should be understood that a thermal warpage is an example of an observed characteristic and that other characteristics may be observed. For example, the semiconductor device component may not undergo any thermal warpage during heating or cooling and as such, an observed characteristic may be that no thermal warpages occurred. In some embodiments, the observed characteristic may include, for example, the occurrence of solder melting or solder joint failure, etc. As such, an observed characteristic may generally include, but are not limited to, any physical characteristics of the semiconductor device component before, during, and/or after undergoing a heating cycle that may be observed.

As such, one or more characteristics of the semiconductor device component, the location in which it occurs, and the time at which it occurs may be observed (e.g., by the camera 306 and/or one or more other image capture devices). Furthermore, and as discussed above, there may be component location data including an indication of the areas of the plate 304 that are covered by the semiconductor device component. Put another way the component location data includes an indication as to the areas of the plate 304 that are directly below the semiconductor device component. As such, an observed characteristic of the semiconductor device may be associated with thermal profile data for an area of the plate 304 directly below where the physical characteristic is located and a specific point in time during the secondary heating cycle. For example, in an instance where a thermal warpage occurs, the location and time at which the thermal warpage occurs may be compared to the temperature profile data generated at step 406 for the corresponding area of the plate 304. Based on the temperature profile data for that corresponding area of the plate 304 the temperature value of that area of the plate 304, at a time in the initial heating cycle generally the same as the time at which the thermal warpage occurred, may be determined.

In this manner, the method 400 may be used to more accurately measure the thermal performance characteristics of a semiconductor device, or component thereof, when compared to conventional systems and methods. For example, the systems and methods described herein enable the automatic generation of comprehensive temperature profile data which may be compared to observed characteristics of a semiconductor device in order to accurately determine the thermal performance thereof at one or more specific temperatures.

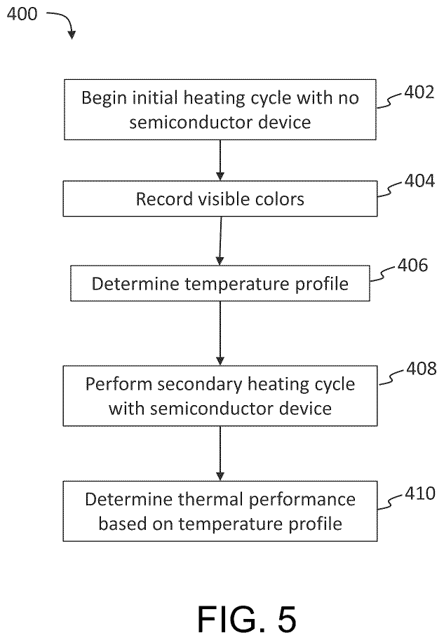

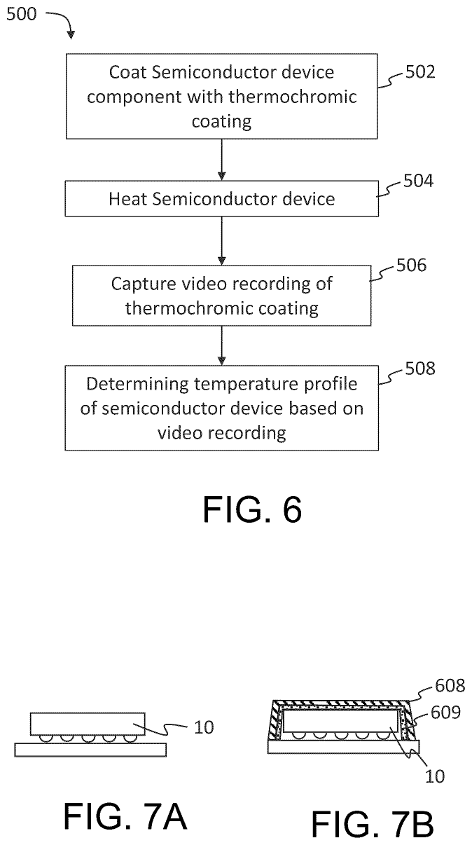

Referring to FIG. 6, there is shown a flowchart illustrating a method, generally designated 500, of measuring the thermal performance of a semiconductor device or one or more components thereof in accordance with an exemplary embodiment of the present disclosure. The method 500 may include the step 502 of coating one or more semiconductor device components with a thermochromic coating. For example, in FIG. 7A, there is shown a semiconductor device component 10 having no thermochromic layer applied thereto and in FIG. 7B, the semiconductor device component 10 is shown as being coated by a thermochromic coating 608. The thermochromic coating 608 may be generally the same as the thermochromic layer 108 except that it substantially covers the semiconductor device component 10. In some embodiments, a plurality of semiconductor device components 10 may be coated with a thermochromic coating 608. In some embodiments, the one or more semiconductor device components may be coated with an electrically insulating material 609 prior to being coated with the thermochromic layer 608. The electrically insulating material 609 is disposed between the surface of the semiconductor device component 10 and the thermochromic coating 608. As such, the thermochromic layer 608, in some embodiments, is applied directly onto the electrically insulating material 609.

In some embodiments, the electrically insulating material 609 may be a material that is electrically insulating and has a thermal conductivity of at least about 120 W/m*K. In some embodiments, the electrically insulating material 609 may be, for example, comprised of a pigmented liquid, colloidal suspension, liquefiable material, or a material having a solid mastic composition that, following application to a surface, converts to a solid film (e.g., a paint or paint-like material). In some embodiments, the electrically insulating material 609 may be generally transparent or may be generally black in color. In some embodiments, the electrically insulating material 609 is a material having a melting point greater than or equal to 400 degrees Celsius. In some embodiments, the electrically insulating material 609 may have a matte finish. The electrically insulating material 609 may be spray coated onto the semiconductor device component 10. In some embodiments, the semiconductor device component 10 may include one or more of: a printed circuit board, one or more solder pastes, and one or more semiconductor dies.

The method 500 may include the step 504 of heating the one or more semiconductor device components and the thermochromic coating(s). Each semiconductor device 10 coated in a thermochromic coating 608 may be heated using a heating system such as, but not limited to, the heating system 100, 300 discussed above, a conventional oven or a reflow oven. For example, the coated semiconductor device components 10 may be placed in a reflow oven and heated.

The method 500 may include the step 506 of capturing a video recording of the thermochromic coating covering the one or more semiconductor device component 10 while the one or more semiconductor device components 10 are being heated. For example, an image capture device included in the heating system (e.g., camera similar to cameras 106, 306 included in heating systems 100, 300) may be used to record images and/or videos of the thermochromic coating(s) 608 covering the one or more semiconductor device components 10 during heating. In some embodiments, a digital image correlation (DIC) device (e.g., micro-DIC) may be used to record images of the thermochromic coating 608 and semiconductor device component 10. In instances where the heating system is a reflow oven, there may be one or more cameras or video capture devices coupled to the reflow oven and configured to capture color images of the coated semiconductor device 10 during heating. The video recording may include, a visual indication of one or more colors of visible at one or more areas of the thermochromic coating 608 at one or more points in time. For example, the video recording generated at step 506 may be generally similar to the video recordings generated in the methods 200 and/or 400 as discussed above, except that the thermochromic layer 608 is coating the semiconductor device component 10 and not the corresponding plate 104, 304.

In some embodiments, the method 500 may include the step 508 of determining a temperature profile (e.g., heat map) of the semiconductor device component based on the video recording. For example, the video recording generated at step 506 may be transmitted to a processor (e.g., a controller) and the processor may be configured to determine the temperature profile of one or more of the semiconductor device components based on the received video recording. Although not illustrated, the processor may be generally similar to, or included in, a controller that is generally the same as controller 110 and/or 310. As such, the processor will not be discussed in further detail. In some embodiments, the processor may determine the temperature profile of the semiconductor device components 10 based on the visual indication of colors visible at the corresponding thermochromic layer 608 at different points in time.

In this manner, in instances where thermal warpages and/or other thermal related defects occur the processor may be configured to associate the area(s) of the semiconductor device component 10 where the warpage occurred with the respective temperature defined by the determined thermal profile. For example, in an instance where one or more areas of a semiconductor device component experiences a thermal warpage caused by the heating, the processor may be configured to associate the one or more areas where thermal warpage occurred and the time at which they occurred with the respective temperature of that area at the same point in time. As such, the processor may be configured to determine one or more thermal warpage temperatures for the semiconductor device component 10. In this manner, the method 500 of the present disclosure may be used to reduce the number of thermal related defects for semiconductor device components by improving the accuracy in which thermal performance may be measured. For example, in response to determining a thermal warpage temperature for one or more of the semiconductor device components, the amount of heat output by a heating system (e.g., a reflow oven) may be preemptively adjusted to be below the determined one or more thermal warpage temperatures.

It will be appreciated by those skilled in the art that changes could be made to the exemplary embodiments shown and described above without departing from the broad inventive concepts thereof. It is understood, therefore, that this invention is not limited to the exemplary embodiments shown and described, but it is intended to cover modifications within the spirit and scope of the present invention as defined by the claims. For example, specific features of the exemplary embodiments may or may not be part of the claimed invention and various features of the disclosed embodiments may be combined. The words “right”, “left”, “lower” and “upper” designate directions in the drawings to which reference is made. Unless specifically set forth herein, the terms “a”, “an” and “the” are not limited to one element but instead should be read as meaning “at least one”. As used herein, the term “about” may refer to +/−10% of the value referenced. For example, “about 9” is understood to encompass 8.1 and 9.9.

It is to be understood that at least some of the figures and descriptions of the invention have been simplified to focus on elements that are relevant for a clear understanding of the invention, while eliminating, for purposes of clarity, other elements that those of ordinary skill in the art will appreciate may also comprise a portion of the invention. However, because such elements are well known in the art, and because they do not necessarily facilitate a better understanding of the invention, a description of such elements is not provided herein.

Further, to the extent that the methods of the present invention do not rely on the particular order of steps set forth herein, the particular order of the steps should not be construed as limitation on the claims. Any claims directed to the methods of the present invention should not be limited to the performance of their steps in the order written, and one skilled in the art can readily appreciate that the steps may be varied and still remain within the spirit and scope of the present invention.

What is claimed is:

1. A heating system comprising:
a plurality of heating elements positioned within a housing, each of the heating elements being configured to generate an amount of heat based on an amount of power supplied to the respective heating element;
a plate positioned within the housing, the plate having a bottom surface facing the plurality of heating elements and a top surface opposite the bottom surface;
a thermochromic layer covering at least a portion of the top surface of the plate;
a camera positioned above the plate, the camera configured to record one or more images of the thermochromic layer at the top surface of the plate; and
a controller in communication with the camera and configured to adjust the amount of power supplied to each heating element independent of one another based on information derived from the one or more images.

2. The heating system of claim 1, wherein each heating element of the plurality of heating elements includes an infrared (IR) light emitting diode (LED).

3. The heating system of claim 1, wherein the plurality of heating elements includes at least 20 heating elements.

4. The heating system of claim 1, wherein the one or more images recorded by the camera includes a plurality of color images of a top surface of the thermochromic layer recorded at different points in time, and
wherein each color image of the top surface of the thermochromic layer at each point in time includes a visual indication of one or more colors visible at the top surface of the thermochromic layer.

5. The heating system of claim 4, wherein the controller is configured to automatically determine for each color image of the top surface of the thermochromic layer at each point in time, one or more temperature values for one or more areas of the thermochromic layer based on the visual indication of the one or more colors visible at the top surface of the thermochromic layer, and
the controller is configured to automatically adjust the amount of power supplied to one or more heating elements based on the one or more temperature values.

6. The heating system of claim 5, wherein the plurality of heating elements are arranged in an array and the plate is positioned above the plurality of heating elements, and
wherein the controller is configured to increase the amount of power supplied to one or more of the heating elements positioned below an area of the thermochromic layer having a temperature value that is less than a temperature value at one or more other areas of the thermochromic layer.

7. The heating system of claim 4 further comprising:
a server in communication with the controller and camera, the server configured to receive the one or more images from the camera and, for each of the one or more images:
automatically determine a temperature heat map including one or more temperature values for one or more areas of the thermochromic layer based on the visual indication of the one or more colors visible at the top surface of the thermochromic layer; and
automatically transmit the temperature heat map to the controller,
wherein the controller is configured to automatically adjust the amount of power supplied to one or more heating elements based on the one or more temperature values included in the temperature heat map.

8. The heating system of claim 1, wherein the controller is configured to increase or decrease the amount of power supplied to the plurality of heating elements independent of one another while the plate is being heated by the plurality of heating elements such that the temperature of the plate is substantially homogeneous across the entire top surface of the plate.

9. The heating system of claim 1, wherein a position of the plate relative to the one or more heating elements is adjustable.

10. A method of measuring thermal performance of a semiconductor device component using the heating system of claim 1, the method comprising:
activating the plurality of heating elements by supplying each with an initial amount of power to cause the plate and thermochromic layer to be heated;
at the camera, recording colors of the thermochromic layer while the thermochromic layer is being heated, and transmitting the recorded colors to the controller;
at the controller, determining from the colors recorded by the camera that one or more areas of the thermochromic layer has a color that is different from a color of one or more other areas of the thermochromic layer and adjusting power supplied to one or more of the heating elements until a color of the thermochromic layer is substantially the same throughout;
at the controller, generating power supply data including an indication of the amount of power supplied to each of the one or more heating elements that resulted in the color of the thermochromic layer being substantially the same throughout; and
placing the semiconductor device component on the plate and activating the heating elements by supplying an amount of power to each of the heating elements based on the power supply data generated by the controller.

11. The method of 10, wherein prior to placing the semiconductor device component on the plate, the plate is cooled.

12. The method of 10, wherein the initial amount of heat output is less than a maximum amount of heat output associated with each heating element.

13. The method of claim 10, wherein the controller is configured to determine a temperature of one or more areas of the thermochromic coating based on the recorded color of the thermochromic coating.

14. A method of measuring thermal performance of a semiconductor device component, the method comprising:
providing a heating system having one or more heating elements and a plate positioned above the one or more heating elements, the plate including a thermochromic layer applied to a top surface of the plate;
activating the one or more heating elements to cause the plate and thermochromic layer to be heated and capturing a video recording of the thermochromic layer while the thermochromic layer is being heated;
determining, based on the video recording of the thermochromic layer, a temperature profile of the plate;
positioning a semiconductor device component on the plate;
activating the one or more heating elements to cause the semiconductor device component to be heated; and
in response to heating the semiconductor device component, determining one or more thermal performance characteristics of the semiconductor device component based on observed characteristics of the semiconductor device component and the determined temperature profile of the plate.

15. The method of claim 14, wherein the observed characteristics of the semiconductor device component include thermal induced warpage of the semiconductor device component.

16. The method of claim 14, wherein the temperature profile of the plate includes an indication of one or more areas at the top surface of the plate having a temperature that is different from one or more other areas at the top surface of the plate.

17. The method of claim 14, wherein the temperature profile is determined based on one or more colors of the thermochromic coating recorded in the video recording during heating of the thermochromic coating.

18. The method of claim 14, wherein the heating system includes a controller configured to determine a temperature of one or more areas of the plate based on one or more colors of the thermochromic coating recorded in the video recording.

19. A method of measuring thermal performance of a semiconductor device component, the method comprising:
coating at least a portion of the semiconductor device component with an electrically insulating material and substantially covering the electrically insulating material with a thermochromic layer;
at a reflow oven, heating the semiconductor device component and the thermochromic layer;
while heating the semiconductor device component, capturing a video recording of the thermochromic layer, the video recording of the thermochromic layer including a visual indication of one or more visible colors at one or more areas of the thermochromic layer at different points in time;
transmitting the video recording of the thermochromic coating to a processor; and
at the processor, determining, based on the video recording of the thermochromic layer, a temperature profile of the semiconductor device component.

20. The method of claim 19, wherein one or more areas of the semiconductor device component experience warpage caused by the heating, the method further comprising:
associating, at the processor, the one or more areas of the semiconductor device component where warpage occurred with a respective temperature defined by the determined thermal profile to determine a warpage temperature; and
adjusting an amount of heat output by the reflow oven to be below the determined warpage temperature.
